(19) United States
(12) Patent Application Publication
(10) Pub. No.: US 2024/0013850 A1
(43) Pub. Date: Jan. 11, 2024

(54) TECHNIQUES FOR ERROR MITIGATION TO IMPROVE RELIABILITY FOR ANALOG COMPUTE-IN-MEMORY

(71) Applicant: Intel Corporation, Santa Clara, CA (US)

(72) Inventors: Wei WU, Portland, OR (US); Hechen WANG, Portland, OR (US)

(21) Appl. No.: 18/372,482

(22) Filed: Sep. 25, 2023

(51) Int. Cl. G11C 29/52; G11C 7/18; G06F 7/492

(52) U.S. Cl. CPC G11C 29/52; G11C 7/18; G06F 7/4925

(57) ABSTRACT

A compute-in-memory (CiM) circuit or structure arranged to detect errors. Examples include detecting errors associated with weight bits stored to computational nodes included in a CiM circuit or structure based on use of complimented bit values. Examples also include detecting errors in the CiM circuit or structure based on using at least some computational nodes included in an array of computational nodes to monitor for the errors during generation of computation results by other computational nodes included in the array.

### TECHNICAL FIELD

Descriptions are generally related to error mitigation for an analog compute-in-memory (CiM) circuit or structure.

### BACKGROUND

Computer artificial intelligence (AI) has been built on machine learning, particularly using deep learning techniques. With deep learning, a computing system organized as a neural network computes a statistical likelihood of a match of input data with prior computed data. A neural network refers to a plurality of interconnected processing nodes that enable the analysis of data to compare an input to “trained” data. Trained data refers to computational analysis of properties of known data to develop models to use to compare input data. An example of an application of AI and data training is found in object recognition, where a system analyzes the properties of many (e.g., thousands or more) of images to determine patterns that can be used to perform statistical analysis to identify an input object such as a person's face.

Neural networks compute “weights” to perform computations on new data (an input data “word”). Neural networks use multiple layers of computational nodes, where deeper layers perform computations based on results of computations performed by higher layers. Machine learning currently relies on the computation of dot-products and absolute difference of vectors, typically computed with multiply and accumulate (MAC) operations performed on the parameters, input data and weights. Because these large and deep neural networks may include many such data elements, these data elements are typically stored in a memory separate from processing elements that perform the MAC operations.

Due to the computation and comparison of many different data elements, machine learning is extremely compute intensive. Also, the computation of operations within a processor are typically orders of magnitude faster than the transfer of data between the processor and memory resources used to store the data. Placing all the data closer to the processor in caches is prohibitively expensive for the great majority of practical systems due to the need for large data capacities of close proximity caches. Thus, the transfer of data when the data is stored in a memory separate from processing elements becomes a major bottleneck for AI computations. As the data sets increase in size, the time and power/energy a computing system uses for moving data between separately located memory and processing elements can end up being multiples of the time and power used to actually perform AI computations.

Some architectures (e.g., non-Von Neumann computation architectures) may employ CiM techniques to bypass von Neumann bottleneck” data transfer issues and execute convolutional neural network (CNN) as well as deep neural network (DNN) applications. The development of such architectures may be challenging in digital domains since MAC operation units of such architectures are too large to be squeezed into high-density Manhattan style memory arrays. For example, the MAC operation units may be magnitudes of order larger than corresponding memory arrays. For example, in a 4-bit digital system, a digital MAC unit may include 800 transistors, while a 4-bit Static random-access memory (SRAM) cell typically contains 24 transistors. Such an unbalanced transistor ratio makes it difficult, if not impossible to efficiently fuse the SRAM with the MAC unit. Thus, von-Neumann architectures can be employed such that memory units are physically separated from processing units. The data is serially fetched from the storage layer by layer, which results in a great latency and energy overhead.

### BRIEF DESCRIPTION OF THE DRAWINGS

FIG. 1 illustrates an example multiplier architecture.

FIG. 2 illustrates an example first CiM structure.

FIG. 3 illustrates an example second CiM structure.

FIG. 4 illustrates an example first logic flow.

FIG. 5 illustrates an example third CiM structure.

FIG. 6 illustrates an example fourth CiM structure.

FIG. 7 illustrates an example second logic flow.

FIG. 8 illustrates an example first computing system.

FIG. 9 illustrates an example semiconductor apparatus.

FIG. 10 illustrates an example processor core.

FIG. 11 illustrates an example second computing system.

### DETAILED DESCRIPTION

In an era of artificial intelligence, computation is more data-intensive, consumes high energy, demands a high level of performance and requires more storage. It can be extremely challenging to fulfill these requirements/demands using conventional architectures and technologies. Analog CiM is starting to gain momentum due to a potential for higher levels of energy to area efficiency compared to conventional digital counterparts. Advantages of analog computing have been demonstrated in many fields especially in the areas of neural networks, edge processing, Fast Fourier transform (FFT), etc.

Similar to conventional memory architectures, analog CiM architectures can also suffer from various run-time faults that are sometimes due to process, voltage, temperature (PVT) uncertainty. A majority of current analog CiM architecture designs focus on power and performance, but rarely give sufficient consideration for data reliability. Data reliability can be critical for analog CiM architectures deployed in multi-bit representation systems.

Error correction codes (ECCs) represent one method to detect and correct data values maintained in a CiM architecture. However, ECCs can only handle a certain number of errors and can have a capability that is fixed by design. Some other examples of error mitigation techniques include adding redundancy at various levels of a CiM architecture such as redundant rows, redundant columns or redundant banks. Other examples of error mitigation techniques include dual/triple modular redundancy (DMR/TMR), checkpointing, or putting in-situ detection logic as sensors to monitor an environment change to prevent and/or detect potential failures.

Current ECC solutions are a “near-memory” not truly “in-memory” solution for error mitigation for an analog CiM architecture. These current ECC solutions are a “near-memory” solution because post-computation signals are processed after an analog-digital-converter (ADC) converts analog signals to digital signals. Errors in the data maintained in an SRAM memory cell may not be detected after ADC conversion. Also, current ECC solution algorithms, such as Hamming code or slightly modified versions of a Hamming code involve use of ECC logic that is too large and too slow for use with an analog CiM circuit or structure. Also, use of redundant rows, columns or banks, checkpointing, or in-situ detection logic for error mitigation can add an unacceptable amount of circuitry that can make cost to implement these solutions not worth the benefit provided by error mitigation. Further, DMR/TMR can possibly miss systematic errors that would cause the same errors in redundant units.

As described in more details below, this disclosure describes use of redundancy logic that is “in-memory” and does not simply repeat operations of main logic. Also, as described in more details below, a type of in-memory light logic can be arranged to mimic normal operations but have a lower overhead compared to a full scale redundance of logic such as used in DMR/TMR. Real-time PVT changes can be monitored using this in-memory light logic and can also be arranged to operate on the most sensitive settings (e.g., most significant bit (MSB) flipping) to detect failure earlier and thus provide an improved or widened operational guard band.

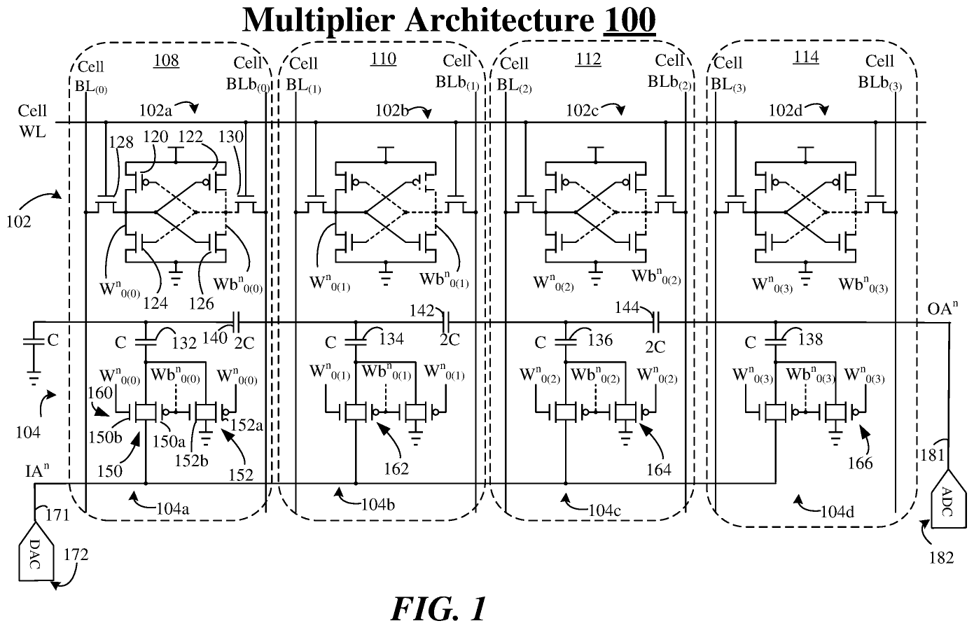

FIG. 1 illustrates an example multiplier architecture 100. In some examples, multiplier architecture 100 can represent a portion of a practical and efficient in-memory computing architecture that includes an integrated MAC unit and memory cell (which can be referred to as an arithmetic memory cell). The arithmetic memory cell employs analog computing methods so that a number of transistors of the integrated MAC unit is similar to a number of transistors of the memory cell (e.g., the transistors are a same order of magnitude) to reduce compute latency. For example, a neural network can be represented as a structure that is a graph of neuron layers flowing from one to the next. The outputs of one layer of neurons are the inputs of the next. To perform these calculations, a variety of matrix-vector, matrix-matrix, and tensor operations are required, which are themselves comprised of many MAC operations. Indeed, there are so many of these MAC operations in a neural network, that such operations may dominate other types of computations (e.g., the Rectified Linear Unit (ReLU) activation and pooling functions). Therefore, the MAC operation is enhanced by reducing data fetches from long term storage and distal memories separated from the MAC unit. Thus, examples described in this disclosure merge the MAC unit with the memory as shown in multiplier architecture 100 to reduce longer latency data movement and fetching (e.g., for neural network applications) Also, analog-based mixed-signal computing that is more efficient than digital (e.g., at low precision), can be employed to reduce data movement costs as compared to conventional digital processors and to also circumvent energy-hungry analog to digital conversions.

As shown in FIG. 1, multiplier architecture 100 includes memory array 102 (which is coupled to one or more unillustrated substrates) and a C-2C based multiplier 104 (which can also be coupled to the one or more substrates) and the memory array 102. C-2C based multiplier 104 shown in FIG. 1 can be configured as a C-2C ladder that includes a series of capacitors C segmented into 4 branches, each branch can be considered a separate multiple shown in FIG. 1 as 304a, 304b, 304c, 304d. As shown in FIG. 1, respective branch/multipliers 304a, 304b, 304c and 304d include respective switches 160, 162, 164 and 166. Also, as shown in FIG. 1, respective branch/multipliers 304a, 304b, 304c and 304d include respective capacitors 132, 134, 136 and 138 that each have a one unit capacitance and include respective capacitors 140, 142, 144 and 146 that each have a two unit capacitance.

In some examples, multipliers 104a, 104b, 104c, 104d can be configured to receive digital signals from memory array 102, execute a multibit computation operation with the plurality of capacitors 132/140, 134/142, 136/144 and 138/146 based on the digital signals and output a first analog signal OAⁿ that is sent towards an analog-digital-converter (ADC) 182 (via a CiM bit line (BL) 181 based on the multibit computation operation. OAⁿ can also be referred to as a output voltage (Vₒᵤₜ) The multibit computation operation can be further based on an input analog signal IAⁿ received via a CiM word line (WL) 171 that originated from a digital-analog-converter (DAC) 172 and can also be referred to as a reference voltage (V_{REF}). Memory array 102, as shown in FIG. 1, includes first, second, third and fourth memory cells 102a, 102b, 102c, 102d. Input activation signal IAⁿ originated from DAC 172 via CiM WL 171 can be provided from a first layer of the neural network, while in-memory multiplier architecture 100 can represent a second layer of the neural network. For example, the C-2C based multiplier 104 may be applied to any layer of a neural network. The superscript “n” indicates that it is applied to (operates on) the nth layer of the neural network. As such, the C-2C based multiplier 104 (e.g., an in-memory multiplier) represents the nth layer of the neural network. IAⁿ can represent an input activation signal at the nth layer, and can be the output of the previous layer (layer n−1). OAⁿ can be the output signal at the nth layer, and it will be fed into the next layer (layer n+1) which can be arranged in similar architecture as shown in FIG. 1 for multiplier architecture 100. DAC 172, CiM WL 171, ADC 182 and CiM BL 181 are described in more detail below in relation to various CiM circuits or structures.

According to some examples, as shown in FIG. 1, each of the plurality of multipliers 104a, 104b, 104c, 104d can be associated with a respective one of memory cells 102a, 102b, 102c, 102d. For example, a first arithmetic memory cell 108 includes multiplier 104a and memory cell 102a such that multiplier 104a receives digital signals (e.g., weights) from the memory cell 102a. A second arithmetic memory cell 110 includes multiplier 304b and memory cell 102b such that multiplier 304b receives digital signals (e.g., weights) from memory cell 102b. A third arithmetic memory cell 112 includes multiplier 104c and memory cell 102c such that multiplier 104c receives digital signals (e.g., weights) from memory cell 102c. A fourth arithmetic memory cell 114 includes multiplier 104d and memory cell 302d such that multiplier 104d receives digital signals (e.g., weights) from memory cell 102d.

In some examples, the weights W, obtained during a neural network training progress and can be preloaded in the network, can be stored in a digital format for information fidelity and storage robustness. With respect to the input activation (which is the analog input signal IAⁿ) and the output activation (which is the analog output signal OAR), the priority can be shifted to the dynamic range and response latency. That is, analog scalars of analog signals, with an inherent unlimited number of bits and continuous time-step, outperforms other storage candidates Thus, multiplier architecture 100 (e.g., a neural network) receives the analog input signal IAⁿ (e.g., an analog waveform) as an input and stores digital bits as its weight storage to enhance neural network application performance, design and power usage. In some examples, memory cells 102a, 102b, 102c, 102d can be arranged to store different bits of a same multibit weight.

According to some examples, arithmetic memory cell 108 of arithmetic memory cell 108, 110, 112, 114 is discussed below as an example for brevity, but it will be understood that arithmetic memory cells 110, 112, 114 are similarly configured to arithmetic memory cell 108. For these examples, memory cell 102a stores a first digital bit of a weight in a digital format. That is, memory cell 102a includes first, second, third and fourth transistors 120, 122, 124 and 126. The combination of the first, second, third and fourth transistors 120, 122, 124 and 126 store and output the first digital bit of the weight. For example, the first, second, third and fourth transistors 120, 122, 124 and 126 output weight signals Wⁿ₀₍₀₎ and W^{bn}₀₍₀₎ which represent a digital bit of the weight. The conductors that transmit the signal weight Wⁿ₀₍₀₎ are represented in FIG. 1 as an unbroken line and the conductors that conduct the weight signal W^{bn}₀₍₀₎ are represented in FIG. 1 as a broken line for clarity. The fifth and sixth transistors 128, 130 can selectively conduct electrical signals from a cell bit line (BL) from among BL₍₀₎ and BL_{b(0)} in response to an electrical signal of a cell word line (WL) meeting a threshold (e.g., voltage of cell WL exceeds a voltage threshold). That is, the electrical signal of the cell WL is applied to gates of the fifth and sixth transistors 128, 130 and the electrical signals of BL₍₀₎ and BL_{b(0)} are applied to sources of the fifth and sixth transistors 128, 130.

In some examples, signals Wⁿ₀₍₀₎ and W^{bn}₀₍₀₎ from memory cell 302a can be provided to multiplier 304a and as shown schematically by the locations of the weight signals Wⁿ₀₍₀₎ and W^{bn}₀₍₀₎ (which represent the digital bit). Multiplier 304a includes capacitors 132, 140, where capacitor 132 can include a capacitance 2C that is double a capacitance C of capacitor 140. Switch 160 of multiplier 304a can be formed by a first pair of transistors 150 and a second pair of transistors 152. The first pair of transistors 150 can include transistors 150a, 150b and selectively couple to input analog signal IAⁿ (e.g., input activation) to capacitor 132 based on the weight signals Wⁿ₀₍₀₎, b^{bn}₀. The second pair of transistors 152 can include transistors 152a, 152b that selectively couple capacitor 132 to ground based on the weight signals Wⁿ₀₍₀₎, w^{bn}₀₍₀₎. Thus, capacitor 132 can be selectively coupled between ground and input analog signal IAⁿ based on weight signals Wⁿ₀₍₀₎, w^{bn}₀₍₀₎. That is, one of the first and second pairs of transistors 150, 152 can be in an ON state to electrically conduct signals, while the other of the first and second pairs of transistors 150, 152 can be in an OFF state to electrically disconnect terminals. For example in a first state, the first pair of transistors 150 can be in an ON state to electrically connect capacitor 132 to input analog signal IAⁿ while the second pair of transistors 152 is in an OFF state to electrically disconnect capacitor 132 from ground. In a second state, the second pair of transistors 152 can be in an ON state to electrically connect capacitor 132 to the ground while the first pair of transistors 150 is in an OFF state to electrically disconnect the capacitor 132 from input analog signal IAⁿ. Thus, capacitor 132 can be selectively electrically coupled to ground or input analog signal IAⁿ based on the weight signals Wⁿ₀₍₀₎, w^{bn}₀.

As mentioned above, arithmetic memory cells 110, 112, 114 can be formed similarly to arithmetic memory cell 108. That is, a cell BL from among BL₍₁₎, BL_{b(1)} and the cell WL can selectively control memory cell 102b to generate and output the weight signals Wⁿ₀₍₁₎ and W^{bn}₀₍₁₎ (which represents a second bit of the weight). Multiplier 104b includes capacitor 134 that can be selectively electrically coupled to ground or input analog signal IAⁿ through switch 162 and based on the weight signals Wⁿ₀₍₁₎ and W^{bn}₀₍₁₎ generated by memory cell 102b.

Similarly, a cell BL from among BL₍₂₎, BL_{b(2)} and the cell WL can selectively control the third memory cell 102c to generate and output weight signals Wⁿ₀₍₂₎ and W b no(2) (which represents a second bit of the weight). Multiplier 104c includes capacitor 136 that can be selectively electrically coupled to ground or input analog signal IAⁿ through switch 164 based on weight signals Wⁿ₀₍₂₎ and W^{bn}₀₍₂₎ generated by memory cell 102b. Likewise, a cell BL from among BL₍₃₎, BL_{b(3)} and the cell WL can selectively control memory cell 102d to generate and output weight signals Wⁿ₀₍₃₎ and W^{bn}₀₍₃₎ (which represents a fourth bit of the weight). Multiplier 104d includes a capacitor 138 that can selectively electrically couple to ground or input analog signal IAⁿ through switch 166 based on weight signals Wⁿ₀₍₃₎ and W^{bn}₀₍₃₎ generated by memory cell 102b. Thus, each of the first-fourth arithmetic memory cells 108, 110, 112, 114 provides an output based on the same input activation signal IAⁿ but also on a different bit of the same weight.

According to some examples, the first-fourth arithmetic memory cells 108, 110, 112, 114 operate as a C-2C ladder multiplier. Connections between different branches of this C-2C ladder multiplier includes capacitors 140, 142, 144. The second, third and fourth multipliers 104b, 104c, 104d are respectively downstream of the first, second and third multipliers 104a, 104b, 104c. Thus, outputs from the first, second and third multipliers 104a, 104b, 104c and/or first, second and third arithmetic memory cells 108, 110, 112 are binary weighted through the capacitors 140, 142, 144. As shown in FIG. 1, the fourth arithmetic memory cell 114 does not include a capacitor at an output thereof since there is no arithmetic memory cell downstream of the fourth arithmetic memory cell 114. The product is then obtained at the output node at the end of the C-2C ladder. Multiplier architecture 100 can generate output analog signal OAⁿ, which corresponds to the below example equation 1. Example equation 1 is an example equation of an m-bit multiplier:

$$IA \times {\sum }_{i = 0}^{m - 1} {W}_{i} \times \frac{1}{{2}^{m - i}} \qquad Equation 1$$

In example equation 1, m is equal to the number of bits of the weight. In this particular example, m−1 is equal to three (m iterates from 0-3) since there are 4 weight bits as noted above. The “i” in example equation 1 corresponds to a position of a weight bit (again ranging from 0-3) such that Wᵢ is equal to the value of the bit at the position. It is worthwhile to note that example equation 1 can be applicable to any m-bit weight value. For example, if hypothetically the weight included more bits, more arithmetic memory cells may be added do the multiplier architecture 100 to process those added bits (in a 1-1 correspondence).

In some examples, multiplier architecture 100 employs a cell charge domain multiplication method by implementing a C-2C ladder for a type of digital-to-analog-conversion of bits of a weight maintained in memory cells. The C-2C ladder can be a capacitor network including capacitors 132, 134, 136, 138 having capacitance C, and capacitors 140, 142, 144 that have capacitance 2C. The capacitors 132, 134, 136, 138, 140, 142, 144 are shown in FIG. 1 as being segmented into branches and can provide low power analog voltage outputs such as OAⁿ to an ADC such as ADC 182.

According to some examples, memory array 102 and the C-2C based multiplier 104 can be disposed proximate to each other. For example, memory array 102 and the C-2C based multiplier 104 may be part of a same semiconductor package and/or in direct contact with each other. Moreover, memory array 102 can be an SRAM structure, but memory array 102 can also be readily modified to be of various memory structures (e.g., dynamic random-access memory, magnetoresistive random-access memory, phase-change memory, etc.) without modifying operation of the C-2C based multiplier 104 mentioned above.

As described in more detail below, a multiplier architecture such as the above-described multiplier architecture 100 can be included in a CiM structure as a node among a plurality of nodes in a tile array. Two error mitigation methods, as described more below, can be implemented using example multiplier architecture 100 in a CiM structure. A first method includes using a digital differential dual computation that pairs main units with redundant units. The main units of a pair operate on original values (e.g., weights) and the redundant units of the pair operate on complemented values. The second method includes lite MAC units mixed with main units. The main units are used to work on multi-bit operations along a column (e.g., same bit line) and a lite MAC unit included in the same column operates, by itself, as a single-bit operation. For both the first and second methods, main units, redundant units and lite MAC unit can be a same or similar structure to multiplier architecture 100.

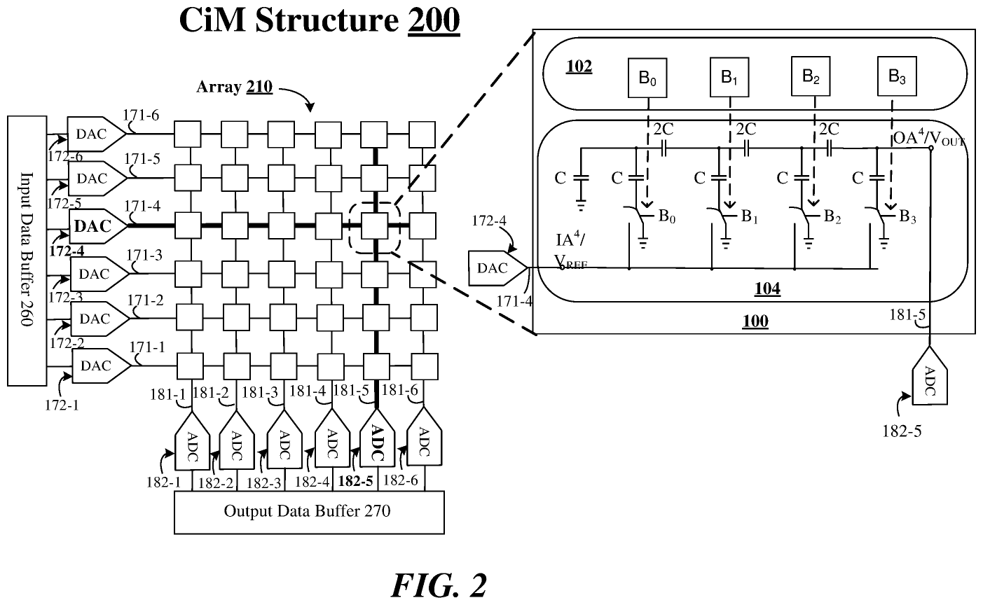

FIG. 2 illustrates an example CiM structure 200. According to some examples, as shown in FIG. 2, CiM structure 200 include an array 210 having a plurality of nodes that represent a complete tile structure. Each node can be considered a computational node of CiM structure 200. For these examples, input data obtained from input data buffer 260 can be converted to an analog input signal IAⁿ or V_{REF} by a DAC from among DACs 172-1 to 172-6 and then multiplied by a group of 4-bit weight elements maintained at each node (e.g., maintained at memory cell 102) along a selected CiM WL from among CiM WLs 171-1 to 171-6. Computed analog outputs OAⁿ or V_{OUT} from the nodes along a CiM BL from among CiM BLs 181-181-6 can be tied together for summation in a charge domain. An ADC from among ADCs 182-1 to 182-6 can then convert the summation into a digital signal/value that is then stored to output data buffer 270.

For example CiM structure 200, an expanded view of a single computational node is depicted in FIG. 1 that shows a simplified representation of multiplier architecture 100. The simplified representation of multiplier architecture 100 indicates that an analog input signal IAⁿ can be received via a CiM WL 171-4 that was generated by DAC 172-4. A multiplication operation can be performed using 4-bit weight elements maintained in b₀, b₁, b₂ and b₃ to generate analog output OAⁿ. OAⁿ can then be sent via a CiM BL 181-5 for summation in a charge domain with other nodes along CiM BL 181-5 for eventual conversion of the summation by ADC 182-5 into a digital signal/value that can then be stored to output data buffer 270.

Examples are not limited to an array that includes nodes arranged in a 6×6 tile structure as shown in FIG. 2. Also, examples are not limited to 4-bit weight elements maintained at each node. Also, examples are not limited to 6 DACs or 6 ADCs.

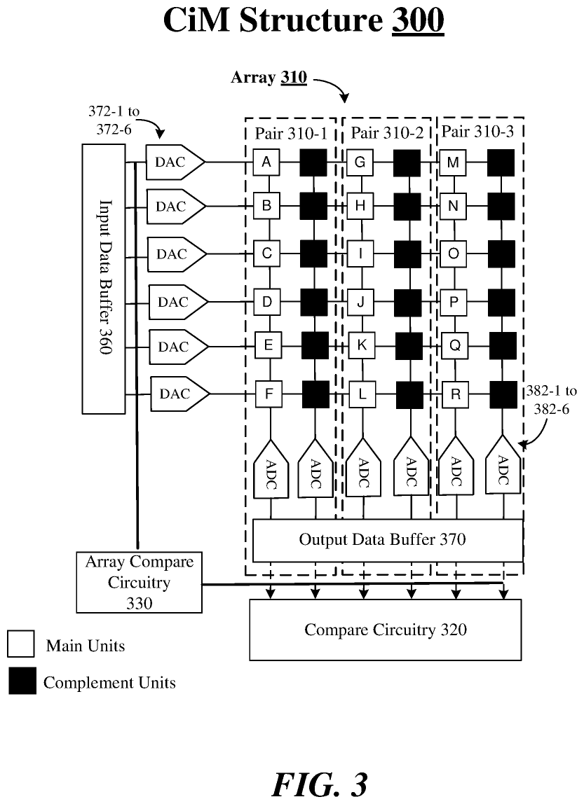

FIG. 3 illustrates an example CiM structure 300. In some examples, as shown in FIG. 3, CiM structure 300 includes an array 310 arranged in a 6×6 tile structure similar to what is shown in FIG. 2 for array 210. Also, CiM structure 300 is shown as including DACs 372-1 to 372-6 to receive input data from an input data buffer 360 and ADCs 382-1 to 382-6 to receive summations in a charge domain and provide converted digital output date to output data buffer 370. Examples are not limited to a 6×6 tile structure, any number or rows and columns for a tile structure are contemplated by this disclosure.

According to some examples, different from CiM structure 200 in FIG. 2, CiM structure 300 is shown as including pair compare circuitry 320 and array compare circuitry 330. Also, array 310 is arranged into pairs 310-1, 310-2 and 310-3. As Shown in FIG. 3, each pair includes a column of main units (white boxes) along a first CiM BL and a column of compliment units (grey boxes) along a second CiM BL. For these examples, main units and complement units can include a same or substantially similar multiplier architecture such as multiplier architecture 100 mentioned above to perform one task. However, the values loaded to a group of weight bits of a complement unit is a complemented value of a group of weight bits loaded to a corresponding main unit. For example, complement unit A′ of pair 310-1 would be loaded with a complement value of corresponding main unit A. For this example, if the group of weight bits of main unit A is an 8-bit value of 01110011, the complemented 8-bit value of complement unit A′ would be 10001100. In other words, each bit of the main unit are flipped to generate the complemented value to be used by the corresponding complement unit. The summation of the results from the two complemented paths along each respective CiM BL should always match to 255/256*V_{REF} for 8-bit complemented values as shown by example equation 2:

$${V}_{OUT \_ main} = {V}_{REF} {\sum }_{i = 0}^{7} ( {B}_{i} \times \frac{1}{{2}^{8 - i}} ) = \frac{1}{{2}^{8}} {V}_{REF} \times B [ 7 : 0 ] \\ {V}_{OUT \_ compliment} = {V}_{REF} {\sum }_{i = 0}^{7} ( {\overline{B}}_{i} \times \frac{1}{{2}^{8 - i}} ) = \frac{1}{{2}^{8}} {V}_{REF} \times \overline{B [ 7 : 0 ]} \\ {V}_{OUT \_ main} + {V}_{OUT \_ compliment} = \frac{255}{256} {V}_{REF} \qquad Equation 2$$

If the path has multiple nodes, the total V_{REF} is equal to a summation of all individual V_{REF}

In some examples, pair compare circuitry 320 can be arranged to compare the summation of the results between two complemented paths included in a pair. For example, compare circuitry 320 can include comparator circuits or comparison logic to compare a summation value from the main units and complemented units included in pair 310-1 to an expected summation value of 255/256*V_{REF} that is a summation of input values to the main units and complemented units included in pair 310-1. The comparison to be made following conversion of the summations to digital signals/values. If the summation value of pair 310-1 matches the expected summation value, then no error is detected. If the summation values don't match the expected value, an error is detected. Responsive to a detected error, mitigation actions can include causing a reloading of weight bits to the memory cells included in all or at least a portion of the main units of pair 310-1. Since the summation value is compared to the expected value after the summation results are converted to a digital signal by ADCs 382-1 and 382-2, the comparison is done outside of the analog array and is in the digital domain.

According to some examples, array compare circuitry 330 can be arranged to sum the results from all complemented paths included in pairs 310-1, 310-2 and 310-3. This array summation can be based on a third path that is shown in FIG. 3 as being outside of array 310. For these examples, array compare circuitry 330 can include comparator circuits or comparison logic to compared the array summation to an expected summation that is based on 255/256*V_{REF} being proportional to a digital input vector that was provided to array 310. The expected summation is based on 8-bit weight values being loaded to each of the main and complement units of array 310. If the array summation doesn't match the expected summation, an error is detected. As a result, all main/complement pair comparisons would fail simultaneously and indicate a possible storage error for 8-bit weight values stored to one or more of the main units. This detected storage error could be distinguished from a computational path error through array 310. Responsive to a detected storage error, mitigation actions can include causing a reloading of weight bits to the memory cells include in all or at least a portion of the main units of pairs 310-1, 310-2 or 310-3. Since the array summation is compared after summation/computation results are converted to a digital signal/value by ADCs 382-1 to 382-6, the comparison is done outside of the analog array and is done in the digital domain.

Flow diagrams as illustrated herein provide examples of sequences of various process actions. The flow diagrams can indicate operations to be executed by a software or firmware routine, as well as physical operations. A flow diagram can illustrate an example of the implementation of states of a finite state machine (FSM), which can be implemented in hardware and/or software. Although shown in a particular sequence or order, unless otherwise specified, the order of the actions can be modified. Thus, the illustrated diagrams should be understood only as examples, and the process can be performed in a different order, and some actions can be performed in parallel. Additionally, one or more actions can be omitted; thus, not all implementations will perform all actions.

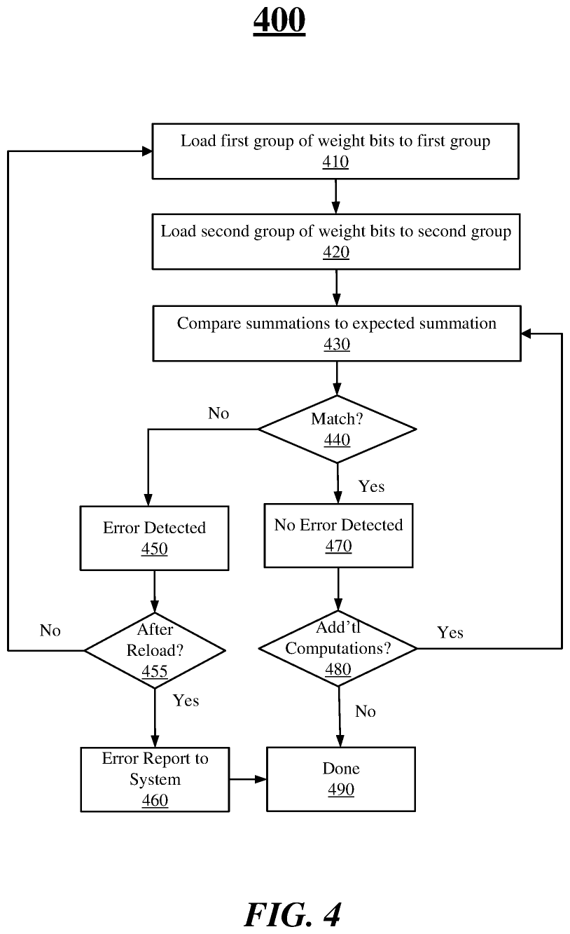

FIG. 4 illustrates an example logic flow 400. According to some examples, logic flow 400 can represent an example logic flow associated with error detection of weight bits stored at nodes included in a CiM structure based on a digital differential dual computation. Logic flow 400 can be implemented by circuitry, logic, or features of a CiM structure such as CiM structure 300 shown in FIG. 3 such as pair compare circuitry 320 or array compare circuitry 330. Examples are not limited to the circuitry, logic, or features of CiM structure 300.

In some examples, at block 410, first group of weight bits are loaded to a first group of computational nodes arranged along a first bit line of a CiM structure. For example, the first group of computational nodes can include the main units included in pair 310-1 of CiM structure 300.

According to some examples, at block 420, second group of weight bits are loaded a second group of computational nodes arranged along a second bit line of the CiM structure. For these examples, the second group of weight bits can include complimented bit values compared to bit values included in the first group of weight bits. The second group of computation nodes can include the complement units included in pair 310-1 of CiM structure 300.

In some examples, at block 430, a summation of a first computation result of the first group and a second computation result of the second group is compared to an expected summation. For these examples, the expected summation can be based on a summation of input values (voltages) to the first and second groups of computational nodes. The comparison, for example, can be implemented by compare circuitry 320 to compare computation results generated by the main units and complement units included in pair 310-1. As mentioned above, this comparison can occur in the digital domain, after voltage summations are converted from analog signals to digital signals.

According to some examples, at decision block 440, a determination is made as to whether the summation matches the expected summation. If the summation does not match the expected summation, logic flow moves to block 450. If the summation matches the expected summation, logic flow moves to block 470.

According to some examples, moving from decision block 440 to block 450, an error is detected based on the summation not matching the expected summation. For these example, this lack of a match can indicate an error (e.g., a bit flip error) has possibly occurred in the first and the second group of weight bits loaded to that main units or complement units included in pair 310.

In some examples, at decision block 455, a determination is made as to whether the first and the second group of weight bits have already been reloaded. In other words, the error was detected after a reload. If the error was not detected after reload, logic flow 400 can return to block 410 to reload weight bits. The reloading of the weight bits could mitigate some types of errors such as soft errors that can cause bits to flip. If the error was detected after reload, logic flow 400 moves to block 460.

According to some examples, moving from decision block 455 to block 460, an error report to system is generated. For these examples, the error report can be based on an assumption that reloading the weight bits did not correct the error and the error could be caused by more than a soft bit error such as a bit flip. Following the error report, flow 400 moves to block 490 and logic flow 400 is done.

In some examples, moving from decision block 440 to block 470, no error is detected.

According to some examples, at decision block 480, if additional computations are to occur, logic flow 400 moves to block 430 for continued comparisons of summations for these additional computations to the expected summation. For example, since no errors were detected, it can be assumed that the weight bits have not been flipped or changed since loading and therefore, the weight bits do not have to be reloaded and can be used for subsequent computations. If there are no additional computations, logic flow 400 moves to block 490 and logic flow 400 is done.

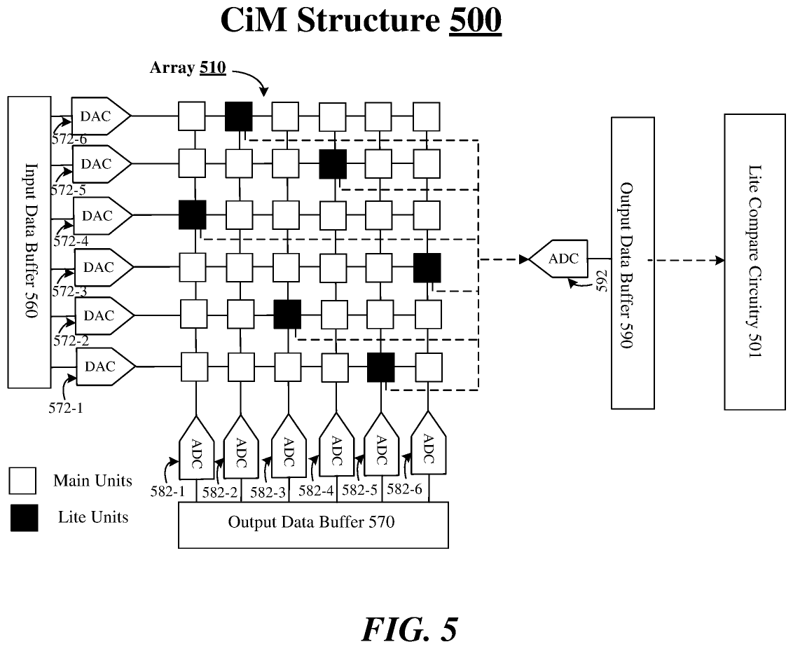

FIG. 5 illustrates an example CiM structure 500. In some examples, as shown in FIG. 5, CiM structure 500 includes an array 510 arranged in a 6×6 tile structure similar to what is shown in FIG. 2 for array 210 and in FIG. 3 for array 310. Also, CiM structure 500 is shown as including DACs 572-1 to 572-6 to receive input data from an input data buffer 560 and ADCs 582-1 to 582-6 to receive summations in a charge domain and provide converted digital output date to output data buffer 570.

According to some examples, different from CiM structure 200 in FIG. 2, CiM structure 500 is shown to include main unit (white box) and lite unit (grey box) nodes in array 510. Also different from CiM structure 200, is that the lite units can be arranged to provide outputs to a single ADC 592 for which a summation of the output values from all the lite units is converted to a digital signal and stored in output data buffer 590. For these examples, lite units are merged in the 6×6 tile array 510 such that at least one lite unit is included in each row and at least one lite unit is included in each column of array 510. A lite unit can have a same multiplier architecture as described above for multiplier architecture 100. A unit is identified as “lite” because it operates by itself while main units operate on matrix multiplication operations that sum results along a same column. In other words, a given lite unit can receive an input analog signal IAⁿ but rather than output a computation result to a next unit in a CiM BL, the same received input analog IAⁿ can be passed or forwarded to the next unit along the CiM BL or can be passed to an ADC at the end of the CiM BL, if the given lite unit is the last unit along a given CiM BL. However, a computation result is still generated by the given lite unit but that computation result is sent as an analog output OAⁿ that is to be summed with analog outputs OAⁿ generated by the other lite units and summation of the analog outputs can be converted to a digital signal by ADC 592 and then stored to output data buffer 590.

In some examples, bit weight values can be preloaded to the lite units to attempt to detect bit flip errors that have a greatest impact on computations performed by the main units included in array 510. For example, MSBs for weight values stored to the main units. For example, a preloaded weight value of 63 if a 6-bit weight value is being used by the main units or a preloaded weight value of 31 if a 5-bit weight value is being used. As mentioned above, lite units are arranged such that there is at least one lite unit per row and column of array 510. This arrangement allows the lite units to serve as monitoring agents to monitor process, voltage, temperature (PVT) or any environmental change in real time as computations are performed by the main units of array 510 to detect errors (e.g. systemic or bit flip errors). For these examples, compare circuitry 501 can include comparator circuits or compare logic to compare the summed digital signal/value to an expected summed value that is based on the preloaded weight values. It the summed value does not match the expected summed value, then an error is detected. The error may have been caused, for example, by systemic issue such as a PVT issue and/or environmental changes that flipped at least one bit that altered at least one of the preloaded bit values to the lite units. That PVT issue and/or environmental changes could have also flipped bits for weight values loaded to the main units. Therefore, to mitigate possible errors in computations by the main units, a reloading of weight values to the memory cells included in all or at least a portion of the main units of array 510 can occur. Also, the weight values are also reloaded to the lite units to continue to monitor PVT or any environmental change in real time.

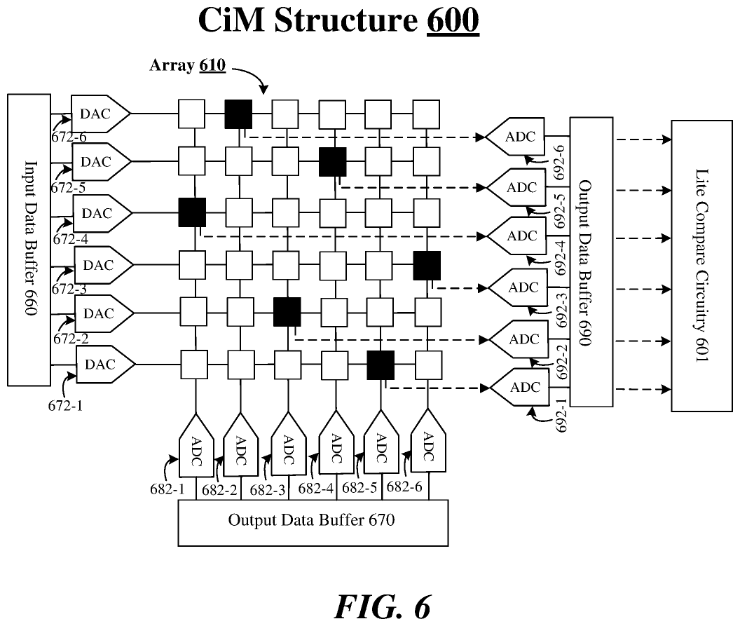

FIG. 6 illustrates an example CiM structure 600. In some examples, as shown in FIG. 6, CiM structure 600 includes an array 610 arranged in a same 6×6 tile structure as shown in FIG. 5 for array 510. Also, CiM structure 500 is shown as including DACs 672-1 to 672-6 to receive input data from an input data buffer 660 and ADCs 682-1 to 682-6 to receive summations in a charge domain and provide converted digital output date to output data buffer 570. However, different from CiM structure 500, CiM structure 600 has individual ADCs from among ADCs 690-1 to 690-6 to convert analog output signals to digital signals/values received from lite units merged in the 6×6 tile array 610, the digital values to be stored to output data buffer 690.

According to some examples, having a 1:1 lite unit to ADC ratio can allow for greater granularity in detecting errors in array 610 verses using a single ADC for all lite units as shown in FIG. 5 for CiM structure 500. For example, compare circuitry 601 can include comparator circuits or compare logic to compare a digital signal value converted by ADC 628-6 that was based on a computed value received from the lite unit included in the top row of array 610 to an expected value based on a preloaded weight value to that same lite unit. If the received computed value and expected value do not match, then an error is detected. Also, if compare circuitry 601 determines that other computed values received at the other 5 ADCs that include 690-1, 690-2, 690-3, 690-4 and 690-5, rather than reload all weight values to all the main units of array 610, only the main units in the same CiM BL or same CiM WL as the top lite unit in array 610 are reloaded.

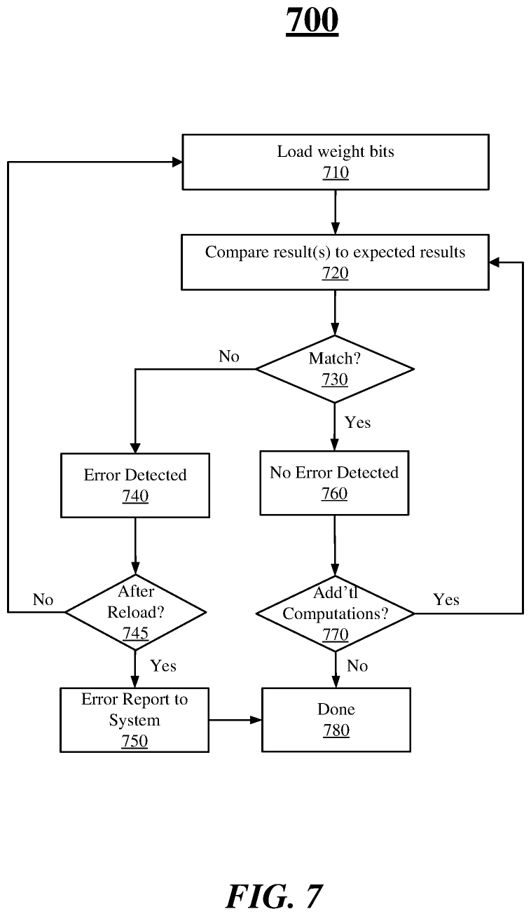

A larger number of ADCs shown for CiM structure 600 in FIG. 6 can consume additional space and consume additional power compared to use of a single ADC as shown for CiM structure 500 in FIG. 7. Also, additional comparator circuits or logic can be needed in lite compare circuitry 601 to compare received computed values to expected values. In some examples, higher ratios of lite units to ADCs can attempt to strike a balance between error detection granularity and costs associated with additional power, space and complexity. For example, a ratio of 3:1 that has a first 3 lite units to a first ADC and a second 3 lite units to a second ADC or a ratio of 2:1 that has pairs of lite units to respective first, second and third ADCs.

FIG. 7 illustrates an example logic flow 700. According to some examples, logic flow 700 can represent an example logic flow associated with error detection and mitigation of weight bits stored at nodes in a CiM structure via use of lite units merged in an array of the nodes in the CiM structure. Logic flow 700 can be implemented by circuitry, logic, or features of a CiM structure such as CiM structures 500 or 600 shown in FIG. 5 or 6 such as lite compare circuitry 501/601. Examples are not limited to the circuitry, logic, or features of CiM structures 500 or 600.

In some examples, at block 710, weight bits are loaded to a portion of computational nodes included in an array of computational nodes of a CiM structure. For example, weight bits can be loaded to lite units of array 510 of CiM structure 500 or array 610 of CiM structure 600.

According to some examples, at block 720, at least one computation result of the portion of computational nodes of the array are compared to an expected result. For these examples, the expected result can be based on the weight bits loaded to the portion of computational nodes. For example, lite compare circuitry 501, 601 can compare at least one computation result for lite nodes included in array 510, 610 to an expected result. Also, the comparison can enable a monitoring for errors in CiM structure 500, 600 during generation of computation results by the main units included in array 510, 610. This comparison, for example, can occur in the digital domain.

In some examples, at decision block 730, a determination is made as to whether the at least one computation result matches the expected result. If the at least one computation result does not match the expected result, logic flow 700 moves to block 740. If the at least one computation result matches the expected result, logic flow moves to block 760.

According to some examples, moving from decision block 730 to block 740, an error is detected based on the at least one computation result not matching the expected result.

In some examples, at decision block 745, a determination is made as to whether weight bits have already been reloaded. In other words, the error was detected after a reload. If the error was not detected after reload, logic flow 700 can return to block 710 to reload weight bits. If the error was detected after reload, logic flow moves to block 750.

According to some examples, moving from decision block 745 to block 750, an error report to system is generated. For these examples, the error report can be based on a reloading of the weight bits not correcting a previously detected error and that additional reloading may not correct the error. Following the error report, flow 700 moves to block 780 and logic flow 700 is done.

In some examples, moving from decision block 730 to block 760, no error is detected.

According to some examples, at decision block 770, if additional computations are to occur, logic flow 700 moves to block 720 for continued comparisons of computation results for additional computations to the expected result. For example, since no errors were detected, it can be assumed that the weight bits have not been flipped or changed since loading and therefore, the weight bits do not have to be reloaded and can be used for subsequent computations. If there are no additional computations, logic flow 700 moves to block 780 and logic flow 700 is done.

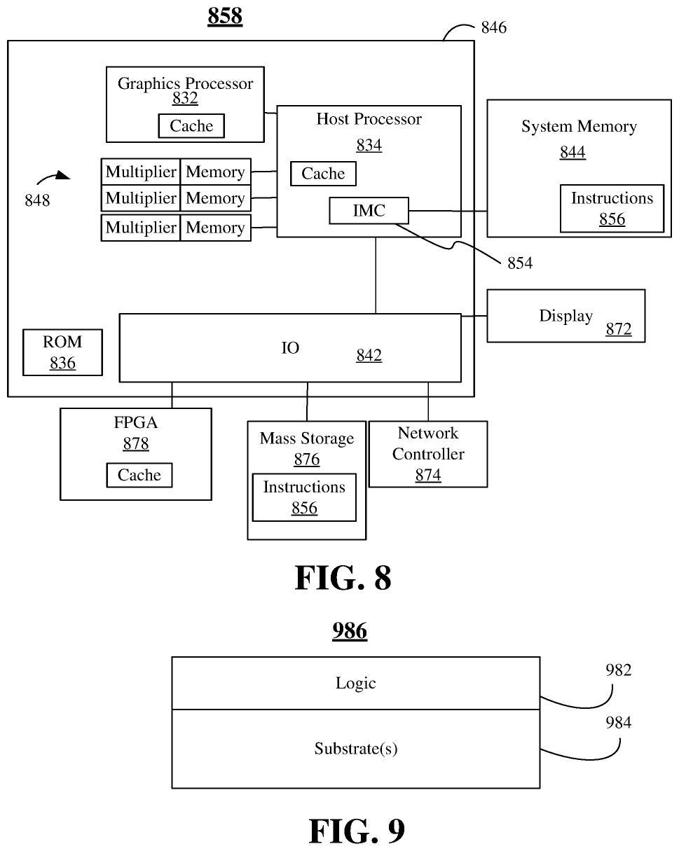

FIG. 8 illustrates an example of a memory-efficient computing system 858. The system 858 may generally be part of an electronic device/platform having computing functionality (e.g., personal digital assistant/PDA, notebook computer, tablet computer, convertible tablet, server), communications functionality (e.g., smart phone), imaging functionality (e.g., camera, camcorder), media playing functionality (e.g., smart television/TV), wearable functionality (e.g., watch, eyewear, headwear, footwear, jewelry), vehicular functionality (e.g., car, truck, motorcycle), robotic functionality (e.g., autonomous robot), etc., or any combination thereof. In the illustrated example, the system 858 includes a host processor 834 (e.g., CPU) having an integrated memory controller (IMC) 854 that is coupled to a system memory 844 with instructions 856 that implement some aspects of the embodiments herein when executed.

The illustrated system 858 also includes an input output (IO) module 842 implemented together with the host processor 834, a graphics processor 832 (e.g., GPU), ROM 836 and arithmetic memory cells 848 on a semiconductor die 846 as a system on chip (SoC). The illustrated IO module 842 communicates with, for example, a display 872 (e.g., touch screen, liquid crystal display/LCD, light emitting diode/LED display), a network controller 874 (e.g., wired and/or wireless), FPGA 878 and mass storage 876 (e.g., hard disk drive/HDD, optical disk, solid state drive/SSD, flash memory) that may also include the instructions 856. Furthermore, the SoC 846 may further include processors (not shown) and/or arithmetic memory cells 848 dedicated to artificial intelligence (AI) and/or neural network (NN) processing. For example, the system SoC 846 may include vision processing units (VPUs), tensor processing units (TPUs) and/or other AI/NN-specific processors such as arithmetic memory cells 848, etc. In some embodiments, any aspect of the embodiments described herein may be implemented in the processors and/or accelerators dedicated to AI and/or NN processing such as the arithmetic memory cells 848, the graphics processor 832 and/or the host processor 834. The system 858 may communicate with one or more edge nodes through the network controller 874 to receive weight updates and activation signals.

It is worthwhile to note that the system 858 and the arithmetic memory cells 848 may implement in-memory multiplier architecture 100 (FIG. 1), CiM structure 200 (FIG. 2), CiM structure 300 (FIG. 3), CiM structure 500 (FIG. 5) or CiM structure 600 (FIG. 6) already discussed. The illustrated computing system 858 is therefore considered to implement new functionality and is performance-enhanced at least to the extent that it enables the computing system 858 to execute operate on neural network data at a lower latency, reduced power and with greater area efficiency.

FIG. 9 illustrates an example semiconductor apparatus 986 (e.g., chip, die, package). The illustrated apparatus 986 includes one or more substrates 984 (e.g., silicon, sapphire, gallium arsenide) and logic 982 (e.g., transistor array and other integrated circuit/IC components) coupled to the substrate(s) 984. In an embodiment, the apparatus 986 is operated in an application development stage and the logic 982 performs one or more aspects of the embodiments described herein, for example, in-memory multiplier architecture 100 (FIG. 1), CiM structure 200 (FIG. 2), CiM structure 300 (FIG. 3), CiM structure 500 (FIG. 5) or CiM structure 600 (FIG. 6) already discussed. Thus, the logic 982 receives, with a first plurality of multipliers of a multiply-accumulator (MAC), first digital signals from a memory array, where the first plurality of multipliers includes a plurality capacitors. The logic 982 executes, with the first plurality of multipliers, multibit computation operations with the plurality of capacitors based on the first digital signals. The logic 982 generates, with the first plurality of multipliers, a first analog signal based on the multibit computation operations. The logic 982 may be implemented at least partly in configurable logic or fixed-functionality hardware logic. In one example, the logic 982 includes transistor channel regions that are positioned (e.g., embedded) within the substrate(s) 984. Thus, the interface between the logic 982 and the substrate(s) 984 may not be an abrupt junction. The logic 982 may also be considered to include an epitaxial layer that is grown on an initial wafer of the substrate(s) 984.

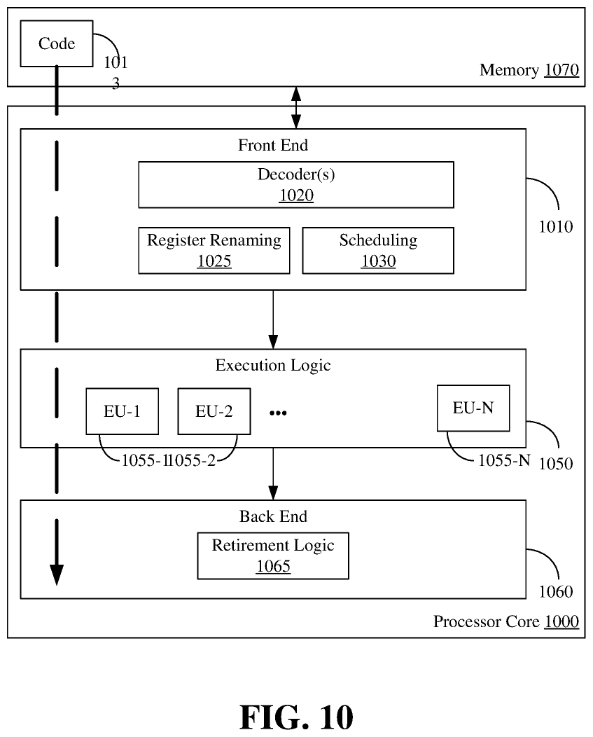

FIG. 10 illustrates an example processor core 1000 according to one embodiment. The processor core 1000 may be the core for any type of processor, such as a micro-processor, an embedded processor, a digital signal processor (DSP), a network processor, or other device to execute code. Although only one processor core 1000 is illustrated in FIG. 10, a processing element may alternatively include more than one of the processor core 1000 illustrated in FIG. 10. The processor core 1000 may be a single-threaded core or, for at least one embodiment, the processor core 1000 may be multithreaded in that it may include more than one hardware thread context (or “logical processor”) per core.

FIG. 10 also illustrates a memory 1070 coupled to the processor core 1000. The memory 1070 may be any of a wide variety of memories (including various layers of memory hierarchy) as are known or otherwise available to those of skill in the art. The memory 1070 may include one or more code 1013 instruction(s) to be executed by the processor core 1000, wherein the code 1013 may implement one or more aspects of the embodiments such as, for example, in-memory multiplier architecture 100 (FIG. 1), CiM structure 200 (FIG. 2), CiM structure 300 (FIG. 3), CiM structure 500 (FIG. 5) or CiM structure 600 (FIG. 6) already discussed. The processor core 1000 follows a program sequence of instructions indicated by the code 1013. Each instruction may enter a front end portion 1010 and be processed by one or more decoders 1020. The decoder 1020 may generate as its output a micro operation such as a fixed width micro operation in a predefined format, or may generate other instructions, microinstructions, or control signals which reflect the original code instruction. The illustrated front end portion 1010 also includes register renaming logic 1025 and scheduling logic 1030, which generally allocate resources and queue the operation corresponding to the convert instruction for execution.

The processor core 1000 is shown including execution logic 1050 having a set of execution units 1055-1 through 1055-N. Some embodiments may include a number of execution units dedicated to specific functions or sets of functions. Other embodiments may include only one execution unit or one execution unit that can perform a particular function. The illustrated execution logic 1050 performs the operations specified by code instructions.

After completion of execution of the operations specified by the code instructions, back end logic 1060 retires the instructions of the code 1013. In one embodiment, the processor core 1000 allows out of order execution but requires in order retirement of instructions. Retirement logic 1065 may take a variety of forms as known to those of skill in the art (e.g., re-order buffers or the like). In this manner, the processor core 1000 is transformed during execution of the code 1013, at least in terms of the output generated by the decoder, the hardware registers and tables utilized by the register renaming logic 1025, and any registers (not shown) modified by the execution logic 1050.

Although not illustrated in FIG. 10, a processing element may include other elements on chip with the processor core 1000. For example, a processing element may include memory control logic along with the processor core 1000. The processing element may include I/O control logic and/or may include I/O control logic integrated with memory control logic. The processing element may also include one or more caches.

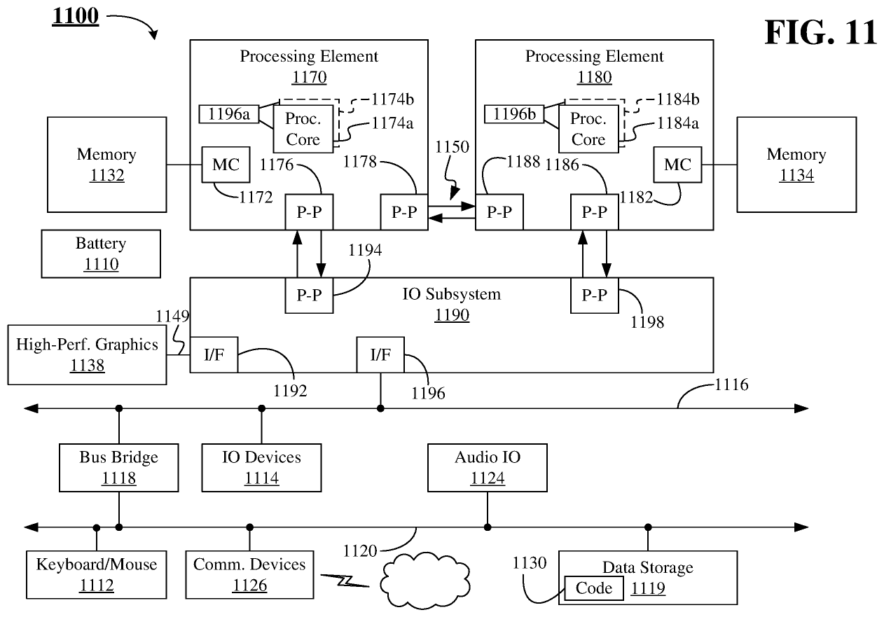

FIG. 11 illustrates an example computing system 1100 embodiment in accordance with an embodiment. Shown in FIG. 11 is a multiprocessor system 1100 that includes a first processing element 1170 and a second processing element 1180. While two processing elements 1170 and 1180 are shown, it is to be understood that an embodiment of the system 1100 may also include only one such processing element.

The system 1100 is illustrated as a point-to-point interconnect system, wherein the first processing element 1170 and the second processing element 1180 are coupled via a point-to-point interconnect 1150. It should be understood that any or all of the interconnects illustrated in FIG. 11 may be implemented as a multi-drop bus rather than point-to-point interconnect.

As shown in FIG. 11, each of processing elements 1170 and 1180 may be multicore processors, including first and second processor cores (i.e., processor cores 1174a and 1174b and processor cores 1184a and 1184b). Such cores 1174a, 1174b, 1184a, 1184b may be configured to execute instruction code in a manner similar to that discussed above in connection with FIG. 11.

Each processing element 1170, 1180 may include at least one shared cache 1196a, 1196b. The shared cache 1196a, 1196b may store data (e.g., instructions) that are utilized by one or more components of the processor, such as the cores 1174a, 1174b and 1184a, 1184b, respectively. For example, the shared cache 1196a, 1196b may locally cache data stored in a memory 1132, 1134 for faster access by components of the processor. In one or more embodiments, the shared cache 1196a, 1196b may include one or more mid-level caches, such as level 2 (L2), level 3 (L3), level 4 (L4), or other levels of cache, a last level cache (LLC), and/or combinations thereof.

While shown with only two processing elements 1170, 1180, it is to be understood that the scope of the embodiments are not so limited. In other embodiments, one or more additional processing elements may be present in a given processor. Alternatively, one or more of processing elements 1170, 1180 may be an element other than a processor, such as an accelerator or a field programmable gate array. For example, additional processing element(s) may include additional processors(s) that are the same as a first processor 1170, additional processor(s) that are heterogeneous or asymmetric to processor a first processor 1170, accelerators (such as, e.g., graphics accelerators or digital signal processing (DSP) units), field programmable gate arrays, or any other processing element. There can be a variety of differences between the processing elements 1170, 1180 in terms of a spectrum of metrics of merit including architectural, micro architectural, thermal, power consumption characteristics, and the like. These differences may effectively manifest themselves as asymmetry and heterogeneity amongst the processing elements 1170, 1180. For at least one embodiment, the various processing elements 1170, 1180 may reside in the same die package.

The first processing element 1170 may further include memory controller logic (MC) 1172 and point-to-point (P-P) interfaces 1176 and 1178. Similarly, the second processing element 1180 may include a MC 1182 and P-P interfaces 1186 and 1188. As shown in FIG. 11, MC's 1172 and 1182 couple the processors to respective memories, namely a memory 1132 and a memory 1134, which may be portions of main memory locally attached to the respective processors. While the MC 1172 and 1182 is illustrated as integrated into the processing elements 1170, 1180, for alternative embodiments the MC logic may be discreet logic outside the processing elements 1170, 1180 rather than integrated therein.

The first processing element 1170 and the second processing element 1180 may be coupled to an I/O subsystem 1190 via P-P interconnects 1176, 1186, respectively. As shown in FIG. 11, the I/O subsystem 1190 includes P-P interfaces 1194 and 1198. Furthermore, I/O subsystem 1190 includes an interface 1192 to couple I/O subsystem 1190 with a high performance graphics engine 1138. In one embodiment, bus 1149 may be used to couple the graphics engine 1138 to the I/O subsystem 1190. Alternately, a point-to-point interconnect may couple these components.

In turn, I/O subsystem 1190 may be coupled to a first bus 1116 via an interface 1196. In one embodiment, the first bus 1116 may be a Peripheral Component Interconnect (PCI) bus, or a bus such as a PCI Express bus or another third generation I/O interconnect bus, although the scope of the embodiments are not so limited.

As shown in FIG. 11, various I/O devices 1114 (e.g., biometric scanners, speakers, cameras, sensors) may be coupled to the first bus 1116, along with a bus bridge 1118 which may couple the first bus 1116 to a second bus 1120. In one embodiment, the second bus 1120 may be a low pin count (LPC) bus. Various devices may be coupled to the second bus 1120 including, for example, a keyboard/mouse 1112, communication device(s) 1126, and a data storage unit 1119 such as a disk drive or other mass storage device which may include code 1130, in one embodiment. The illustrated code 1130 may implement the one or more aspects of such as, for example, in-memory multiplier architecture 100 (FIG. 1), CiM structure 200 (FIG. 2), CiM structure 300 (FIG. 3), CiM structure 500 (FIG. 5) or CiM structure 600 (FIG. 6) already discussed. Further, an audio I/O 1124 may be coupled to second bus 1120 and a battery 1110 may supply power to the computing system 1100.

Note that other embodiments are contemplated. For example, instead of the point-to-point architecture of FIG. 11, a system may implement a multi-drop bus or another such communication topology. Also, the elements of FIG. 11 may alternatively be partitioned using more or fewer integrated chips than shown in FIG. 11.

The following examples pertain to additional examples of technologies disclosed herein.

Example 1. An example CiM structure can include a first group of computational nodes arranged along a first bit line. The first group of computational nodes can be separately arranged to store respective first group of weight bits. The CiM structure can also include a second group of computational nodes arranged along a second bit line. The second group of computational nodes can be separately arranged to store respective second group of weight bits that are complimented bit values compared to bit values included in the first group of weight bits. The CiM structure can also include a first circuitry to compare a summation of a first computation result of the first group and a second computation result of the second group to an expected summation. The expected summation can be based on a summation of input values to the first and second groups of computational nodes. The comparison can be to determine whether an error associated with a storing of the first or the second group of weight bits to respective first and second groups of computational nodes has been detected.

Example 2. The CiM structure of example 1, the first circuitry can compare the summation to the expected summation in a digital domain.

Example 3. The CiM structure of example 1 can also include the first circuitry to determine that an error associated with the storing of the first or the second group of weight bits has occurred based on the comparison of the summation to the expected summation indicating that the summation does not match the expected summation. The first circuitry can also cause the first and the second group of weight bits to be reloaded to respective first and second groups of computational nodes.

Example 4. The CiM structure of example 1 can also include a third group of computational nodes arranged along a third bit line. The third group of computational nodes can be separately arranged to store respective third group of weight bits. The CiM structure can also include a fourth group of computational nodes arranged along a fourth bit line the fourth group of computational nodes separately arranged to store respective fourth group of weight bits that are complimented bit values compared to bit values included in the third group of weight bits. The CiM structure can also include a second circuitry to compare an array summation of the first computation result of the first group, the second computation result of the second group, a third computation result of third group and a fourth computation result of the fourth group to a second expected summation. The second expected summation can be based on input values to the first, second, third and fourth groups of computational nodes. The comparison of the array summation to the second expected summation can determine whether an error associated with a storing of the first, the second, the third or the fourth group of weight bits to respective first, second, third or fourth groups of computational nodes has been detected.

Example 5. The CiM structure of example 4, the second circuitry can also determine that an error associated with the storing of the first, the second, the third or the fourth group of weight bits has occurred based on the comparison of the array summation to the second expected summation indicating that the array summation does not match the second expected summation. The second circuitry can also cause the first, the second, the third and the fourth group of weight bits to be reloaded to respective first, second, third and fourth groups of computational nodes.

Example 6. The CiM structure of example 4, the second circuitry can compare the array summation to the second expected summation in a digital domain.

Example 7. The CiM structure of example 1, the computational nodes of the first group and the second group can individually include SRAM bits cells that are arranged to store weight bits.

Example 8. An example method can include loading first group of weight bits to a first group of computational nodes arranged along a first bit line of a CiM structure. The method can also include loading second group of weight bits to a second group of computational nodes arranged along a second bit line of the CiM structure. The second group of weight bits can include complimented bit values compared to bit values included in the first group of weight bits. The method can also include comparing a summation of a first computation result of the first group and a second computation result of the second group to an expected summation. The expected summation can be based on a summation of input values to the first and second groups of computational nodes. The method can also include determining whether an error associated with a storing of the first or the second group of weight bits to respective first and second groups of computational nodes has been detected.

Example 9. The method of example 8, comparing the summation to the expected summation can occur in a digital domain.

Example 10. The method of example 8 can also include determining that an error associated with the storing of the first or the second group of weight bits has occurred based on the comparison of the summation to the expected summation indicating that the summation does not match the expected summation. The method can also include causing the first and the second group of weight bits to be reloaded to respective first and second groups of computational nodes.

Example 11. The method of example 8 can also include loading third group of weight bits to a third group of computational nodes arranged along a third bit line of the CiM structure. The method can also include loading fourth group of weight bits to a fourth group of computational nodes arranged along a fourth bit line of the CiM structure, the fourth group of weight bits to include complimented bit values compared to bit values included in the third group of weight bits. The method can also include comparing an array summation of the first computation result of the first group, the second computation result of the second group, a third computation result of the third group, and a fourth computation result of the fourth group to a second expected summation. The second expected summation can be based on input values to the first, second, third and fourth groups of computational nodes. The method can also include determining whether an error associated with storing of the first, the second, the third or the fourth group of weight bits to respective first, second, third or fourth groups of computational nodes has been detected based on the comparison of the array summation to the second expected summation.

Example 12. The method of example 11 can also include determining that an error associated with the storing of the first, the second, the third or the fourth group of weight bits has occurred based on the comparison of the array summation to the second expected summation indicating that the summation does not match the expected summation. The method can also include causing the first, the second, the third and the fourth group of weight bits to be reloaded to respective first, second, third and fourth groups of computational nodes.

Example 13. The method of example 11, comparing the array summation to the second expected summation can occur in a digital domain.

Example 14. The method of example 8, the computational nodes of the first group and the second group individually can include SRAM bits cells that are arranged to store weight bits.

Example 15. An example at least one machine readable medium can include a plurality of instructions that in response to being executed by a system can cause the system to carry out a method according to any one of examples 11 to 14.

Example 16. An example apparatus can include means for performing the methods of any one of examples 11 to 14.

Example 17. An example CiM structure can include an array of computational nodes. The CiM structure can also include circuitry to compare at least one computation result of a portion of computational nodes included in the array to an expected result to monitor for errors, the expected result to be based on weight bits loaded to the portion of computational nodes. For these examples, the circuitry can monitor for errors during generation of computation results by a remaining portion of computational nodes included in the array.

Example 18. The CiM structure of example 17 can also include the circuitry to detect an error based on the at least one computation result not matching the expected result and cause weight bits to be reloaded to all computational nodes included in the array.

Example 19. The CiM structure of example 17, the circuitry to compare at least one computation result can include the circuitry to compare computation results from individual computational nodes of the portion of computational nodes to the expected value.

Example 20. The CiM structure of example 17, the circuitry to compare at least one computation results can include the circuitry to compare a summation of the computation results from all computational nodes of the portion of computational nodes to the expected value.

Example 21. The CiM structure of example 17, the weight bits loaded to the portion of computational nodes of the array can include weight bits that include binary l's as most significant bits (MSBs).

Example 22. The CiM structure of example 17, the circuitry to compare the at least one computation result of the portion of nodes to the expected result can include the circuitry to compare in a digital domain.

Example 23. The CiM structure of example 17, the computational nodes included in the array can individually include SRAM bit cells that are arranged to store weight bits.

Example 24. An example method can include loading weight bits to a portion of computational nodes included in an array of computational nodes of a CiM structure. The method can also include monitoring for errors in the CiM structure by comparing at least one computation result of the portion of computational nodes of the array to an expected result. The expected result can be based on the loaded weight bits, wherein monitoring is to occur during generation of computation results by a remaining portion of computational nodes included in the array.

Example 25. The method of example 24 can also include detecting an error in the CiM structure based on the at least one computation result not matching the expected result and causing weight bits to be reloaded to all computational nodes included in the array of computational nodes.

Example 26. The method of example 25, comparing at least one computation result can include comparing computation results from individual computational nodes of the portion of computational nodes to the expected value.

Example 27. The method of example 26, comparing at least one computation results can include comparing a summation of the computation results from all computational nodes of the portion of computational nodes to the expected value.

Example 28. The method of example 24, the weight bits loaded to the portion of computational nodes of the array can include weight bits that include binary l's as most significant bits (MSBs).

Example 29. The method of example 24, comparing the at least one computation result of the portion of nodes to the expected result can occur in a digital domain.

Example 30. The method of example 24, the computational nodes included in the array can individually include SRAM bit cells that are arranged to store weight bits.

Example 31. An example at least one machine readable medium can include a plurality of instructions that in response to being executed by a system can cause the system to carry out a method according to any one of examples 24 to 30.

Example 32. An example apparatus can include means for performing the methods of any one of examples 24 to 30.

To the extent various operations or functions are described herein, they can be described or defined as software code, instructions, configuration, and/or data. The content can be directly executable (“object” or “executable” form), source code, or difference code (“delta” or “patch” code). The software content of what is described herein can be provided via an article of manufacture with the content stored thereon, or via a method of operating a communication interface to send data via the communication interface. A machine readable storage medium can cause a machine to perform the functions or operations described and includes any mechanism that stores information in a form accessible by a machine (e.g., computing device, electronic system, etc.), such as recordable/non-recordable media (e.g., read only memory (ROM), random access memory (RAM), magnetic disk storage media, optical storage media, flash memory devices, etc.). A communication interface includes any mechanism that interfaces to any of a hardwired, wireless, optical, etc., medium to communicate to another device, such as a memory bus interface, a processor bus interface, an Internet connection, a disk controller, etc. The communication interface can be configured by providing configuration parameters and/or sending signals to prepare the communication interface to provide a data signal describing the software content. The communication interface can be accessed via one or more commands or signals sent to the communication interface.

Various components described herein can be a means for performing the operations or functions described. Each component described herein includes software, hardware, or a combination of these. The components can be implemented as software modules, hardware modules, special-purpose hardware (e.g., application specific hardware, application specific integrated circuits (ASICs), digital signal processors (DSPs), etc.), embedded controllers, hardwired circuitry, etc.

It is emphasized that the Abstract of the Disclosure is provided to comply with 37 C.F.R. Section 1.72(b), requiring an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single example for the purpose of streamlining the disclosure. This method of disclosure is not to be interpreted as reflecting an intention that the claimed examples require more features than are expressly recited in each claim. Rather, as the following claims reflect, inventive subject matter lies in less than all features of a single disclosed example. Thus, the following claims are hereby incorporated into the Detailed Description, with each claim standing on its own as a separate example. In the appended claims, the terms “including” and “in which” are used as the plain-English equivalents of the respective terms “comprising” and “wherein,” respectively. Moreover, the terms “first,” “second,” “third,” and so forth, are used merely as labels, and are not intended to impose numerical requirements on their objects.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

What is claimed is:

1. A compute-in-memory structure comprising:
a first group of computational nodes arranged along a first bit line, the first group of computational nodes separately arranged to store respective first group of weight bits;
a second group of computational nodes arranged along a second bit line, the second group of computational nodes separately arranged to store respective second group of weight bits that are complimented bit values compared to bit values included in the first group of weight bits; and
a first circuitry to compare a summation of a first computation result of the first group and a second computation result of the second group to an expected summation, the expected summation based on a summation of input values to the first and second groups of computational nodes, the comparison to determine whether an error associated with a storing of the first or the second group of weight bits to respective first and second groups of computational nodes has been detected.

2. The compute-in-memory structure of claim 1, wherein the first circuitry to compare the summation to the expected summation in a digital domain.

3. The compute-in-memory structure of claim 1, further comprising the first circuitry to:
determine that an error associated with the storing of the first or the second group of weight bits has occurred based on the comparison of the summation to the expected summation indicating that the summation does not match the expected summation; and
cause the first and the second group of weight bits to be reloaded to respective first and second groups of computational nodes.

4. The compute-in-memory structure of claim 1, further comprising:
a third group of computational nodes arranged along a third bit line, the third group of computational nodes separately arranged to store respective third group of weight bits;
a fourth group of computational nodes arranged along a fourth bit line the fourth group of computational nodes separately arranged to store respective fourth group of weight bits that are complimented bit values compared to bit values included in the third group of weight bits; and
a second circuitry to compare an array summation of the first computation result of the first group, the second computation result of the second group, a third computation result of third group and a fourth computation result of the fourth group to a second expected summation, the second expected summation based on input values to the first, second, third and fourth groups of computational nodes, the comparison of the array summation to the second expected summation to determine whether an error associated with a storing of the first, the second, the third or the fourth group of weight bits to respective first, second, third or fourth groups of computational nodes has been detected.

5. The compute-in-memory structure of claim 4, further comprising the second circuitry to:
determine that an error associated with the storing of the first, the second, the third or the fourth group of weight bits has occurred based on the comparison of the array summation to the second expected summation indicating that the array summation does not match the second expected summation; and
cause the first, the second, the third and the fourth group of weight bits to be reloaded to respective first, second, third and fourth groups of computational nodes.

6. The compute-in-memory structure of claim 4, wherein the second circuitry is to compare the array summation to the second expected summation in a digital domain.

7. The compute-in-memory structure of claim 1, wherein the computational nodes of the first group and the second group individually include static random access memory (SRAM) bits cells that are arranged to store weight bits.

8. A method comprising:
loading first group of weight bits to a first group of computational nodes arranged along a first bit line of a compute-in-memory (CiM) structure;
loading second group of weight bits to a second group of computational nodes arranged along a second bit line of the CiM structure, the second group of weight bits to include complimented bit values compared to bit values included in the first group of weight bits;
comparing a summation of a first computation result of the first group and a second computation result of the second group to an expected summation, the expected summation based on a summation of input values to the first and second groups of computational nodes; and
determining whether an error associated with a storing of the first or the second group of weight bits to respective first and second groups of computational nodes has been detected.

9. The method of claim 8, further comprising:
determining that an error associated with the storing of the first or the second group of weight bits has occurred based on the comparison of the summation to the expected summation indicating that the summation does not match the expected summation; and
causing the first and the second group of weight bits to be reloaded to respective first and second groups of computational nodes.

10. The method of claim 8, further comprising:
loading third group of weight bits to a third group of computational nodes arranged along a third bit line of the CiM structure;
loading fourth group of weight bits to a fourth group of computational nodes arranged along a fourth bit line of the CiM structure, the fourth group of weight bits to include complimented bit values compared to bit values included in the third group of weight bits;
comparing an array summation of the first computation result of the first group, the second computation result of the second group, a third computation result of the third group, and a fourth computation result of the fourth group to a second expected summation, the second expected summation based on input values to the first, second, third and fourth groups of computational nodes; and
determining whether an error associated with storing of the first, the second, the third or the fourth group of weight bits to respective first, second, third or fourth groups of computational nodes has been detected based on the comparison of the array summation to the second expected summation.

11. The method of claim 10, further comprising:
determining that an error associated with the storing of the first, the second, the third or the fourth group of weight bits has occurred based on the comparison of the array summation to the second expected summation indicating that the summation does not match the expected summation; and
causing the first, the second, the third and the fourth group of weight bits to be reloaded to respective first, second, third and fourth groups of computational nodes.

12. A compute-in-memory structure, comprising:
an array of computational nodes; and
circuitry to compare at least one computation result of a portion of computational nodes included in the array to an expected result to monitor for errors, the expected result to be based on weight bits loaded to the portion of computational nodes, wherein the circuitry is to monitor for errors during generation of computation results by a remaining portion of computational nodes included in the array.

13. The compute-in-memory structure of claim 12, further comprising the circuitry to:
detect an error based on the at least one computation result not matching the expected result; and
cause weight bits to be reloaded to all computational nodes included in the array.

14. The compute-in-memory structure of claim 12, wherein the circuitry to compare at least one computation result comprises to compare computation results from individual computational nodes of the portion of computational nodes to the expected result.

15. The compute-in-memory structure of claim 12, wherein the circuitry to compare at least one computation results comprises to compare a summation of the computation results from all computational nodes of the portion of computational nodes to the expected result.

16. The compute-in-memory structure of claim 12, wherein the weight bits loaded to the portion of computational nodes of the array comprise weight bits that include binary l's as most significant bits (MSBs).

17. The compute-in-memory structure of claim 12, wherein the circuitry to compare the at least one computation result of the portion of nodes to the expected result comprises the circuitry to compare in a digital domain.

18. The compute-in-memory structure of claim 12, wherein the computational nodes included in the array individually include static random access memory (SRAM) bit cells that are arranged to store weight bits.

19. A method comprising:
loading weight bits to a portion of computational nodes included in an array of computational nodes of a compute-in-memory (CiM) structure; and
monitoring for errors in the CiM structure by comparing at least one computation result of the portion of computational nodes of the array to an expected result, the expected result based on the loaded weight bits, wherein monitoring is to occur during generation of computation results by a remaining portion of computational nodes included in the array.

20. The method of claim 19, further comprising:
detecting an error in the CiM structure based on the at least one computation result not matching the expected result; and
causing weight bits to be reloaded to all computational nodes included in the array of computational nodes.

21. The method of claim 19, wherein comparing at least one computation result comprises comparing computation results from individual computational nodes of the portion of computational nodes to the expected result.

22. The method of claim 19, wherein comparing at least one computation results comprises comparing a summation of the computation results from all computational nodes of the portion of computational nodes to the expected result.

23. The method of claim 19, wherein the weight bits loaded to the portion of computational nodes of the array comprise weight bits that include binary l's as most significant bits (MSBs).
